(19) United States
(12) Patent Application Publication
(10) Pub. No.: US 2008/0200023 A1
(43) Pub. Date: Aug. 21, 2008

(54) METHOD OF FABRICATING MICRO CONNECTORS

(76) Inventor: Ming-Yen Chiu, Ping-Tung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/737,134

(22) Filed: Apr. 18, 2007

(30) Foreign Application Priority Data
Feb. 16, 2007 (TW) 096106273

(51) Int. Cl. H01L 21/4763

(52) U.S. Cl. 438/618; 257/E21.495

(57) ABSTRACT

A wafer is provided, and a first surface of the wafer is etched to form a plurality of through holes. A first surface conductive layer is formed on the first surface, and an internal conductive layer is formed to fill up each through hole. A first insulating layer is formed on the first surface conductive layer. A thinning process is performed to thin a second surface of the wafer so as to expose the internal conductive layer in the through holes. A second surface conductive layer is formed on the second surface, and the second surface conductive layer is electrically connected to the first surface conductive layer via the internal conductive layer.

### BACKGROUND OF THE INVENTION

1. Field of the Invention

The present invention relates to a method of fabricating micro connectors, and more particularly, to a method of fabricating micro connectors with high density and thin thickness having an upside and a downside electrically connected to each other.

2. Description of the Prior Art

Multi-functional and miniature electronic products have become a trend in electronic product development. In practice, each function generally must be realized in an independent chip. In other words, multi-function applications require multiple-chip solutions. However, if connections between independent chips are formed in a printed circuit board (PCB), a size of an electronic product inevitably grows. In order to improve on the problem, the integration of system on a chip (SOC) therefore prevails. However, because the SOC process technology is complicated and has low yield and high price, recent semiconductor packaging devices including integrated circuits and microelectromechanical products are developed using a method of system in a package (SIP) so as to reduce cost and increase product yield.

The main idea of the SIP is to set a plurality of chips that form a multi-function application on a connector, such that connections between each of the plurality of chips occur across the connector. Furthermore, the aforementioned chips and the connector are packaged together to form a system package structure, and chips are electrically connected to one another through a conductive pattern inside the micro connector. Therefore, the micro connector plays an important role in SIP. With the development of the product being miniature, to reduce the size of the system package structure is inevitable, so to improve the size of the micro connector and the connecting method of the chips is an important subject. The conventional micro connector only has electrically connecting points on one side, so a limitation in stacking will happen. Also, although the conventional printed circuit board has the characteristic of an upside and a downside being connected to each other, the size of the conventional printed circuit board is large. Therefore, in order to reduce the package size, to fabricate a micro connector with high density, three-dimensional package, simple processing and mass production become important subjects.

### SUMMARY OF THE INVENTION

It is therefore an object to provide a method of fabricating micro connectors with high density, thin thickness, and the upside and the downside of the micro connectors are electrically connected to each other.

According to a preferred embodiment of the present invention, a method of fabricating micro connectors is provided. First, a wafer is provided, and the wafer comprises a first surface and a second surface. Next, a first dielectric layer is formed on the first surface of the wafer, and then, the first dielectric layer is patterned. The first dielectric layer comprises a plurality of first openings, and the first surface is exposed by the first openings. Subsequently, the first surface exposed by the first openings is etched to form a plurality of through holes. Then, an internal conductive layer is formed in the through holes and fills up each through hole, and a first surface conductive layer is formed on the first dielectric layer. Next, the first surface conductive layer is patterned to expose the first dielectric layer, and a first insulating layer is formed on the first surface conductive layer and the first dielectric layer. Then, a thinning process is performed to thin the second surface of the wafer so as to expose the internal conductive layer in the through holes. Subsequently, a second dielectric layer is formed on the second surface of the wafer, and the second dielectric layer is patterned. The second dielectric layer comprises a plurality of second openings, and each second opening is respectively corresponding to each through hole of the second surface. A second surface conductive layer is formed on the second dielectric layer and fills up each second opening, and the second surface conductive layer is patterned. A second insulating layer is formed on the second surface conductive layer and the second dielectric layer.

The method of fabricating micro connectors of the present invention utilizes a deep etching process, an electroless plating process and a thinning process to fabricate the wafer with through holes so as to let the upside and downside of the micro connector connect to each other. The present invention thins the micro connectors to the required thickness through the thinning process so as to provide a package with small size and high density, and the present invention also has advantages of being simple, continuous and able to mass production.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 17 are schematic diagrams illustrating a method of fabricating micro connectors according to a preferred embodiment of the present invention.

FIG. 18 and FIG. 19 are schematic diagrams illustrating a method of fabricating micro connectors according to another preferred embodiment of the present invention.

### DETAILED DESCRIPTION

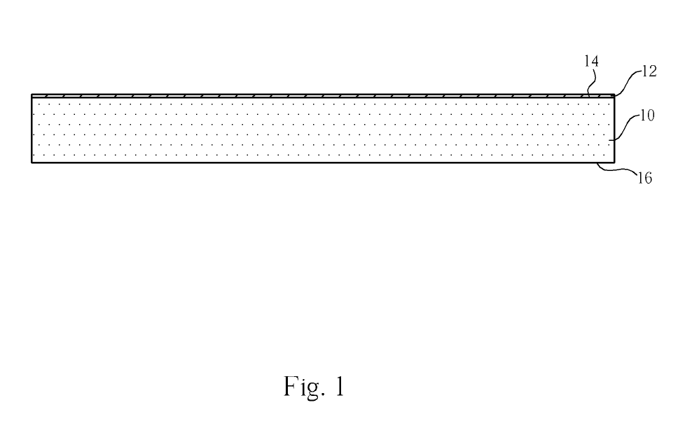

Please refer to FIG. 1 through FIG. 17. FIG. 1 through FIG. 17 are schematic diagrams illustrating a method of fabricating micro connectors according to a preferred embodiment of the present invention. As shown in FIG. 1, first, a wafer 10, such as a silicon wafer, is provided, and the wafer 10 includes a first surface 14 and a second surface 16. Then, a first dielectric layer 12 is formed on the first surface 14 of the wafer 10. In this embodiment, the first dielectric layer 12 is an oxide layer formed by a thermal deposition, and the function of the first dielectric layer 12 provides insulation to avoid leakage current. The forming method and material of the first dielectric layer 12 are not limited to the above-mentioned, and the first dielectric layer 12 can be another insulating material, such as silicon oxide, silicon nitride or silicon oxy-nitride.

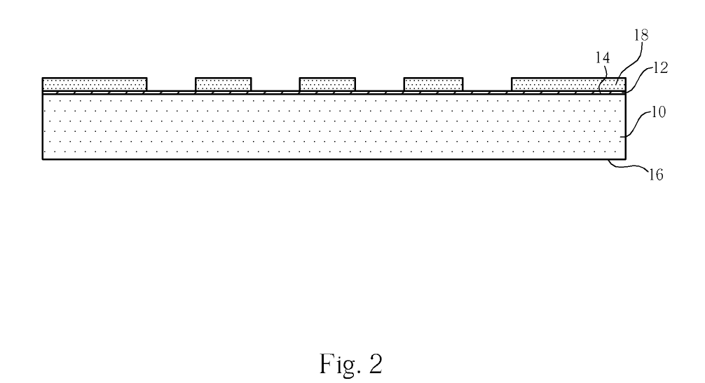

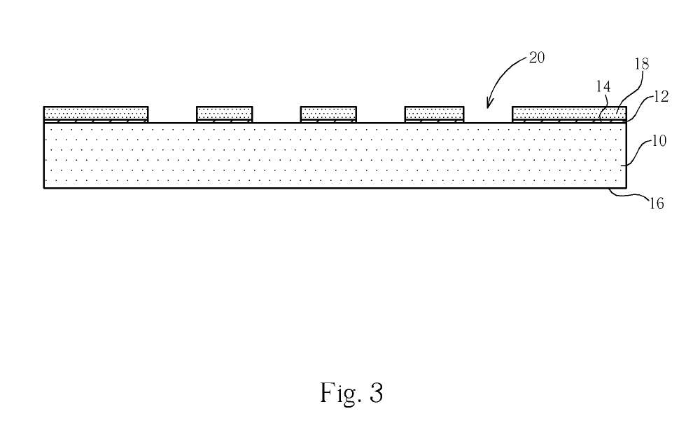

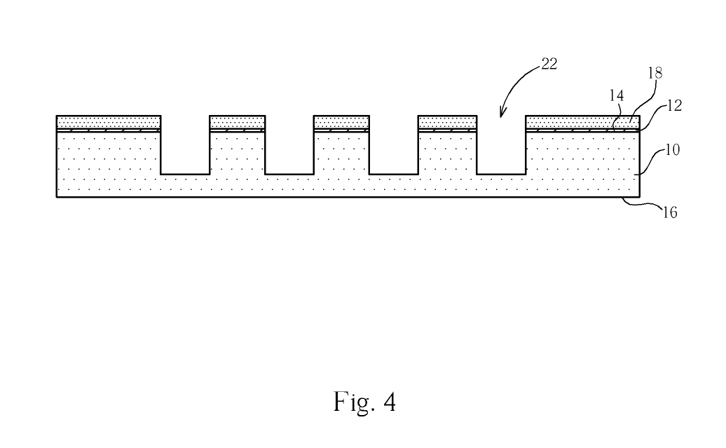

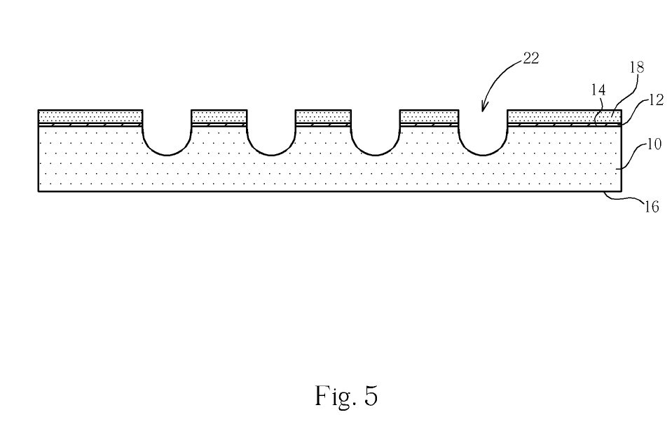

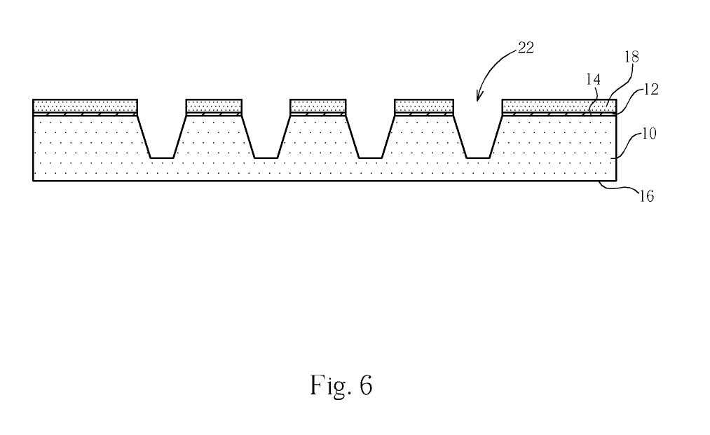

Next, as shown in FIG. 2, a mask pattern 18 is formed on the first dielectric layer 12. The mask pattern 18 can be a photoresist pattern, formed in required form on the wafer 10 by a lithographic process. As shown in FIG. 3, the first dielectric layer 12 is patterned, and the mask pattern 18 can be a mask so that a region of the first dielectric layer 12 not covered by the mask pattern 18 will be etched. The first dielectric layer 12 includes a plurality of first openings 20 corresponding to the mask pattern 18, and the first surface 14 is exposed by the first openings 20. As shown in FIG. 4, the first surface 14 exposed by the first openings 20 is etched to form a plurality of through holes 22. The through holes 22 in this embodiment have vertical sidewalls, but the through holes 22 can have different shapes of sidewalls according to requirements, such as rounded sidewalls or inclined sidewalls, as shown in FIG. 5 and FIG. 6. The etching method for the through holes 22 can be different according to a different shape, such as the vertical sidewalls of the through holes 22 using a reactive ion etching (RIE) process of the dry etching process, the rounded sidewalls of the through holes 22 using a wet etching process using hydrofluoric acid (HF) as an etching solution and the inclined sidewalls of the through holes 22 using potassium hydroxide (KOH), tetramethylammonium hydroxide (TMAH) or ethylenediamine-pyrocatechol-water (EDP) as an etching solution. The depth of the through holes 22 can be modified by the requirements.

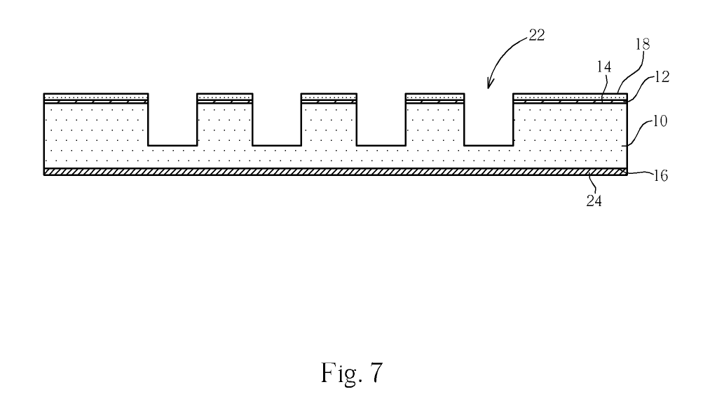

Subsequently, as shown in FIG. 7, a surface protection process is performed on the second surface 16 of the wafer 10, so a surface protection layer 24, such as a photoresist layer, a thermal release tape or a UV tape, is formed on the second surface 16. The thermal release tape or UV tape can adhere to the second surface 16. The function of the surface protection layer 24 is to remove the metal plated on the second surface 16 easily, and the surface protection layer 24 is not limited to the above-mentioned material and also can be other materials, such as wax or polyimide.

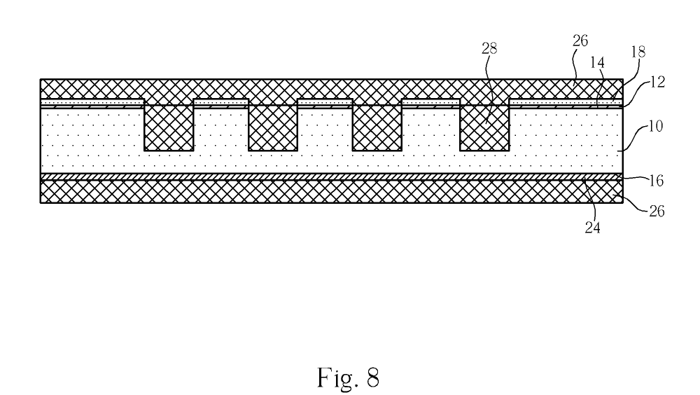

Next, as shown in FIG. 8, a surface activation process is performed on the wafer 10. Then, an electroless plating process is performed to form the internal conductive layer 28 in the through holes to fill up each through hole and to form a metal layer 26 on the mask pattern 18 and the second surface 16 of the wafer 10. Before the electroless plating process, the surfaces of the wafer 10 requiring to be plated have to be treated with surface activation so that the electroless plating process can be performed. In this embodiment, after the surface activation process, the electroless plating process of this embodiment is to put the wafer 10 into a solution of electroless plating metal. In addition, the surface activation process can use a dry plasma bombardment or use a palladium chloride solution that the wafer 10 is put into so as to increase the activation energy of the surface requiring to be plated. The palladium chloride solution is used to let the palladium ions adhere to the surface requiring to be plated. In addition, the plating metal in the electroless plating process can be gold, copper or another metal.

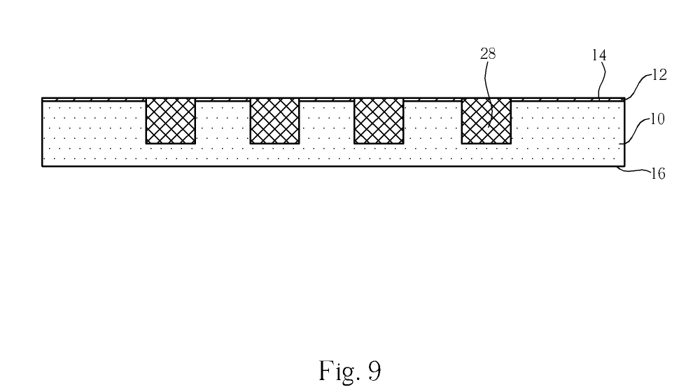

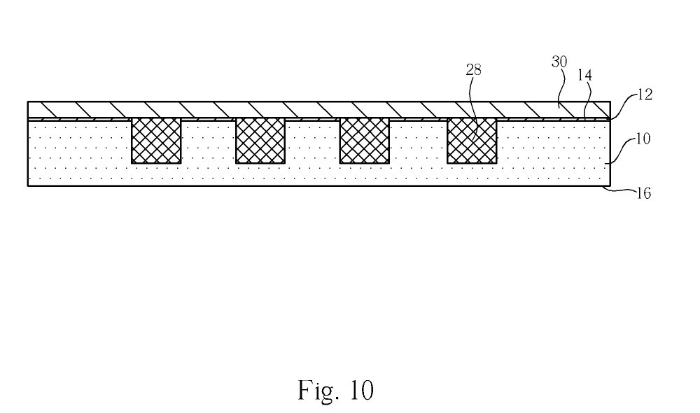

As shown in FIG. 9, the surface protection layer 24 of the second surface 16 and the metal layer 26 plated thereon are removed. Then, a lift off process is performed to remove the mask pattern 18 and the metal layer 26 plated thereon so as to expose the internal conductive layer 28 in the through holes and the first dielectric layer 12. Subsequently, as shown in FIG. 10, a plating process is performed to plate a first surface conductive layer 30 on the first surface 14. It is a better method to make the material of the first surface conductive layer 30 be the same as the one of the internal conductive layer 28 plated in the electroless plating process. The plating process in this embodiment can be evaporation, sputtering or another plating process.

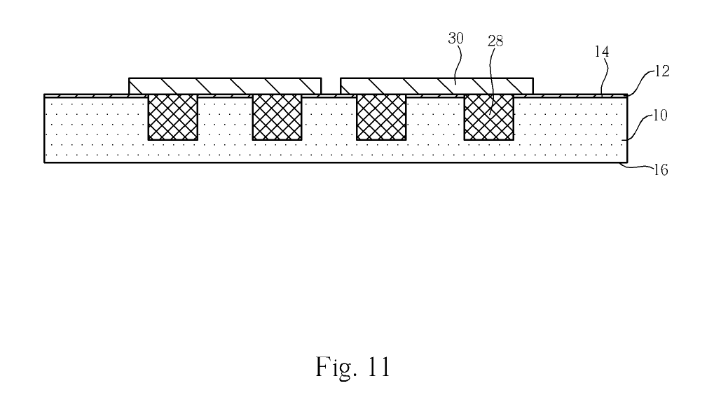

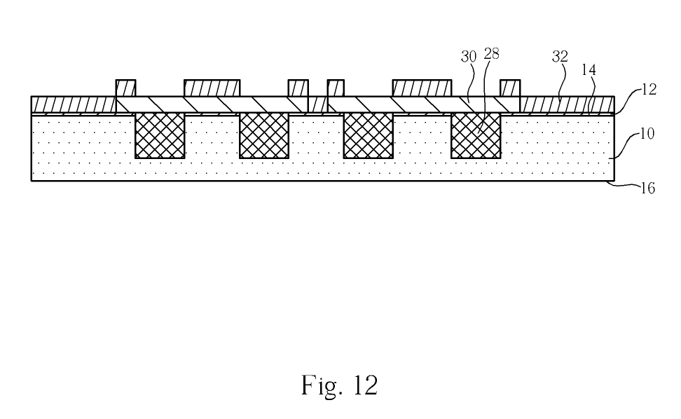

As shown in FIG. 11, the first surface conductive layer 30 is patterned to form a required pattern. As shown in FIG. 12, a first insulating layer 32 is formed on the first surface conductive layer 30 and the first dielectric layer 12. The required pattern of the first insulating layer 32 is defined according to the patterns of the chips needing connection. The exposed first surface conductive layer 30 can be utilized as electrically connecting points of the micro connectors to the external chips (not shown in figure).

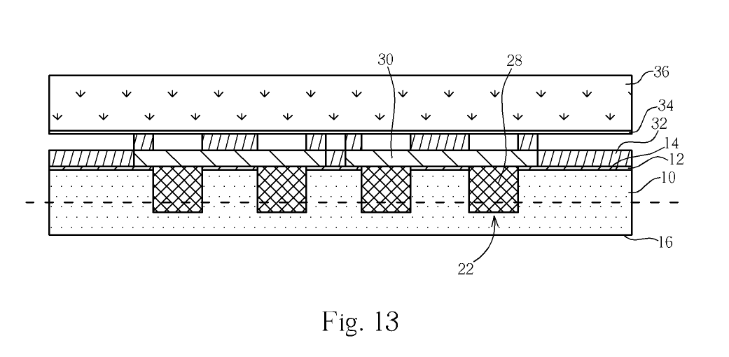

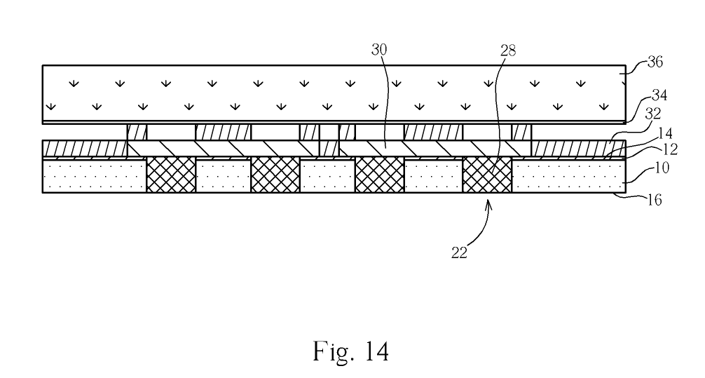

As shown in FIG. 13, a handle wafer 36 adheres to the first insulating layer 32 with an adhesive layer 34. The adhesive layer 34 can be any bonding materials e.g. thermal release tape or UV tape. As shown in FIG. 14, a thinning process is performed, and the second surface 16 of the wafer 10 is thinned to expose the internal conductive layer 28 in the through holes 22. The function of the handle wafer 36 is to ensure that the manufacturing process can still keep running when the wafer 10 is thinned to less than 200 μm. Therefore, when the thickness after thinning is more than 200 μm, the first insulating layer 32 does not need to adhere to the adhesive layer 34 and the handle wafer 36. In addition, the thinning process can be grinding and/or chemical mechanical polishing process to polish the wafer 10 to the required thickness according to the requirements.

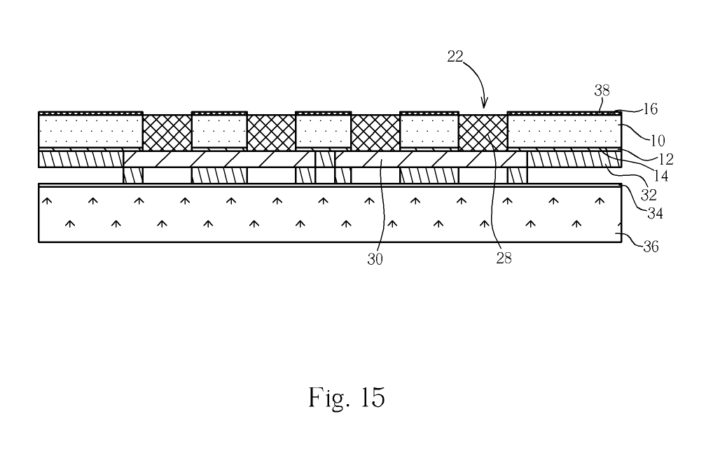

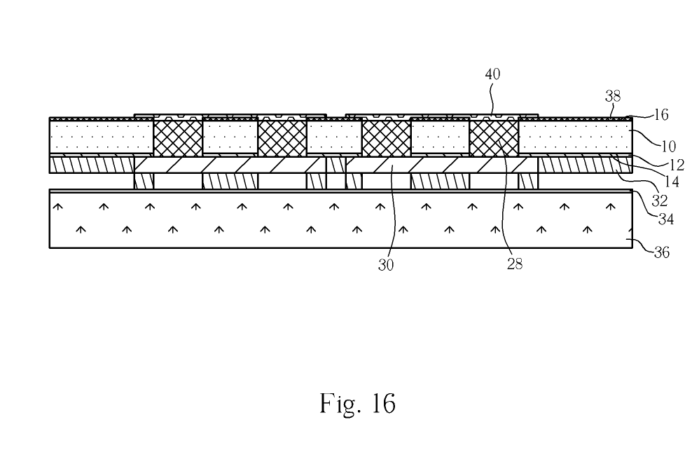

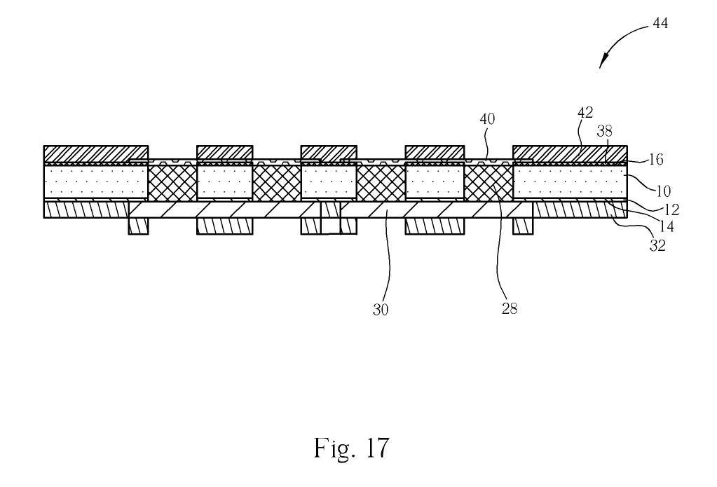

As shown in FIG. 15, the wafer 10 is turned over, and a second dielectric layer 38 is formed on the second surface of the wafer 10. Then, the second dielectric layer 38 is patterned, and the second dielectric layer 38 includes a plurality of second openings corresponding to the through holes 22 of the second surface 16. As shown in FIG. 16, a second surface conductive layer 40 is formed on the second dielectric layer 38, and fills up each second opening. Then, the second surface conductive layer 40 is patterned to form a required conductive pattern, and the second surface conductive layer 40 is electrically connected to the internal conductive layer 40 through the second openings. Then, as shown in FIG. 17, a second insulating layer 42 is formed on the second surface conductive layer 40 and the second dielectric layer 38. Last, cutting the wafer 10 and removing the adhesive layer 34 and the handle wafer 36 forms a required micro connector 44. In addition, the second surface conductive layer 40 exposed by the second insulating layer 42 is the electrically connecting points of the micro connectors 44 used to connect external chips (not shown in figure). The second surface conductive layer 40 and the first surface conductive layer 30 are electrically connected to each other through the internal conductive layer 28. The micro connector 44 of the present invention has a characteristic of the upside and downside thereof electrically connected to each other so that the chips disposed on and below the micro connector 44 can be vertically stacked and electrically connected to each other.

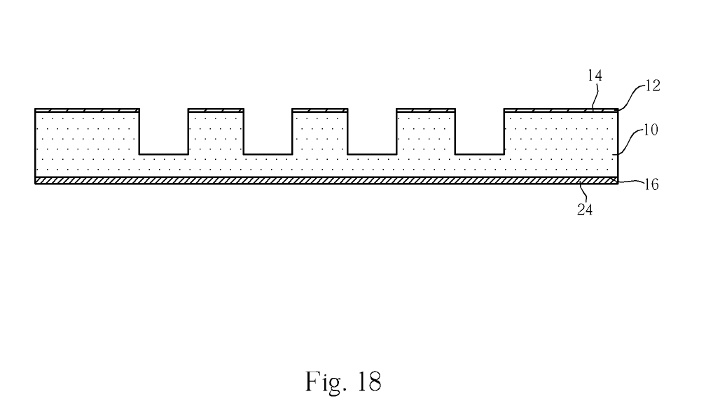

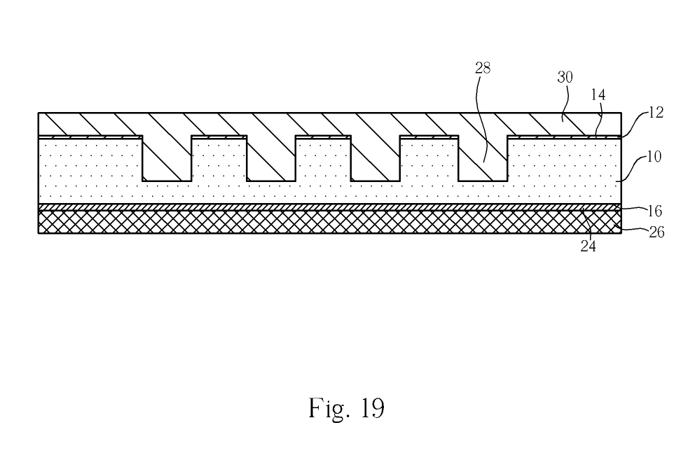

Please refer to FIG. 18 and FIG. 19 and also refer to FIG. 1 through FIG. 7 and FIG. 10 through FIG. 17. FIG. 18 and FIG. 19 are schematic diagrams illustrating a method of fabricating micro connectors according to another preferred embodiment of the present invention. For convenience, like process will not be detailed redundantly in this embodiment, and like device will use the same signal. The difference between this embodiment and the above-mentioned embodiment is from performing the surface protection process on the second surface 16 to patterning the first surface conductive layer 30. As shown in FIG. 18, after performing the surface protection process on the second surface 16 in this embodiment, a mask pattern 18 is removed, and then, a surface activation process is performed on the whole wafer 10. Next, as shown in FIG. 19, an electroless plating process is performed to form a first surface conductive layer 30 on the first dielectric layer 12 and to fill up each of a plurality of through holes 22 with an internal conductive layer 28. At the same time, a metal layer 26 is formed on the second surface 16. Next, as shown in FIG. 10, a surface protection layer 24 on the second surface 16 and the metal layer 26 plated on the second surface 16 are removed, so the internal conductive layer 28 is formed in the through holes 22, and the first surface conductive layer 30 is formed on the first dielectric layer 12. Last, the first surface conductive layer 30 is patterned as the above-mentioned embodiment, and the process thereafter is also the same as the above-mentioned embodiment.

In summary, the method of fabricating micro connectors of the present invention utilizes the deep etching process, the electroless plating process and the thinning process to fabricate the wafer with through holes having an upside and downside connected to each other so that different chips can be stacked in three dimensions and electrically connected to each other by the micro connectors of the present invention. In addition, the present invention thins the micro connectors to the required thickness through the thinning process so as to provide a package with small size and high density. The present invention utilizing semiconductor processes to fabricate micro connectors also has advantages of being simple, continuous and able to mass production.

Those skilled in the art will readily observe that numerous modifications and alterations of the device and method may be made while retaining the teachings of the invention.

What is claimed is:

1. A method of fabricating micro connectors, comprising:
providing a wafer, the wafer comprising a first surface and a second surface;
forming a first dielectric layer on the first surface of the wafer and patterning the first dielectric layer, the first dielectric layer comprising a plurality of first openings and the first surface exposed by the first openings;
etching the first surface exposed by the first openings to form a plurality of through holes;
forming an internal conductive layer in the through holes and filling up each through hole with the internal conductive layer, and forming a first surface conductive layer on the first dielectric layer;
patterning the first surface conductive layer to expose the first dielectric layer;
forming a first insulating layer on the first surface conductive layer and the first dielectric layer;
performing a thinning process to thin the wafer from the second surface so as to expose the internal conductive layer in the through holes;
forming a second dielectric layer on the second surface of the wafer and patterning the second dielectric layer, the second dielectric layer comprising a plurality of second openings and each second opening respectively corresponding to each through hole of the second surface;
forming a second surface conductive layer on the second dielectric layer and filling up each second opening with the second surface conductive layer and patterning the second surface conductive layer; and
forming a second insulating layer on the second surface conductive layer and the second dielectric layer.

2. The method of claim 1, wherein the first surface conductive layer is electrically connected to the internal conductive layer and the second surface conductive layer.

3. The method of claim 1, wherein the patterned first dielectric layer further comprises a mask pattern, and the step of forming the internal conductive layer in the through holes and filling up each through hole with the internal conductive layer, and forming the first surface conductive layer on the first dielectric layer comprises:
forming the internal conductive layer in the through holes and forming a metal layer on the mask pattern;
performing a lift off process and removing the mask pattern and the metal layer on the mask pattern; and
forming the first surface conductive layer on the first dielectric layer.

4. The method of claim 3, wherein the internal conductive layer is made by an electroless plating process.

5. The method of claim 3, wherein the first surface conductive layer is made by evaporation or sputtering.

6. The method of claim 1, wherein the internal conductive layer and the first surface conductive layer are made by a same electroless plating process.

7. The method of claim 1, further comprising a step of performing a surface activation process on the wafer before forming the internal conductive layer in the through holes.

8. The method of claim 7, further comprising a step of performing a surface protection process on the second surface of the wafer before the step of performing the surface activation process.

9. The method of claim 8, wherein the surface protection process forms a photoresist layer on the second surface layer.

10. The method of claim 8, wherein the surface protection process adheres a thermal release tape or a UV tape to the second surface.

11. The method of claim 1, further comprising bonding a handle wafer to the first surface of the wafer with an adhesive layer.

12. The method of claim 11, wherein the adhesive layer comprises a thermal release tape or a UV tape.

13. The method of claim 1, wherein each through hole has vertical sidewalls.

14. The method of claim 1, wherein each through hole has rounded sidewalls.

15. The method of claim 1, wherein each through hole has inclined sidewalls.
